(19) United States
(12) Patent Application Publication
(10) Pub. No.: US 2007/0274020 A1
(43) Pub. Date: Nov. 29, 2007

(54) Electrostatic Chuck And Chuck Base Having Cooling Path For Cooling Wafer

(75) Inventors: Hee Yong Park, Suwon-si (KR); Jin Tai Kim, Bucheon-si (KR); Kyu Ha Lee, Suwon-si (KR); Kwan Tae Park, Suwon-si (KR); Sang Young Oh, Suwon-si (KR); Hwi Gon Jang, Suwon-si (KR)

Correspondence Address: CHRISTIE, PARKER & HALE, LLP, PO BOX 7068, PASADENA, CA, 91109-7068, US

(73) Assignee: ADAPTIVE PLASMA TECHNOLOGY CORPORATION, Gyeonggi-do (KR)

(21) Appl. No.: 10/583,978

(22) PCT Filed: Dec. 22, 2004
(86) PCT No.: PCT/KR04/03387

§ 371 Date: Apr. 26, 2007

(30) Foreign Application Priority Data
Dec. 22, 2003 (KR) 10-2003-0094412

(51) Int. Cl. H01L 21/3065

(52) U.S. Cl. 361/234

(57) ABSTRACT

The electrostatic chuck comprises a chuck base for supporting a wafer, a dielectric film mounted on the chuck base, the dielectric film having an electrode for supplying direct current voltage to provide an electrostatic force to fix the wafer, the electrode disposed in the dielectric film, and a cooling channel for supplying refrigerant to the dielectric film to control the temperature of the wafer. At least two first cooling channel parts are formed at the surface of the dielectric film corresponding to the edge part of the wafer such that the first cooling channel parts form concentric circles, second cooling channel parts formed at the surface of the dielectric film such that the first cooling channel parts are connected to each other through the second cooling channel parts, first through channels formed through the dielectric film for supplying the refrigerant to the first and second cooling channel parts, and a second through channel formed through the center of the dielectric film for supplying the refrigerant to the center of the wafer.

### TECHNICAL FIELD

The present invention relates to semiconductor device manufacturing equipment, and, more particularly, to an electrostatic chuck (ESC) and a chuck base having a cooling path or channel for cooling a wafer.

### BACKGROUND ART

In a reaction chamber of semiconductor device manufacturing equipment, for example, a dry etcher, is mounted a chuck for supporting a semiconductor wafer during a process. The chuck may be an electrostatic chuck. The chuck is mounted on a chuck base, which is disposed at the rear surface of the chuck. The chuck base serves to support the chuck. The chuck base is provided with a cooling channel for maintaining a constant temperature of the chuck, and therefore, uniformly cooling the semiconductor wafer located on the chuck.

The electrostatic chuck fixes the wafer using an electrostatic force. To this end, the electrostatic chuck has a structure for generating an electrostatic force or electrostatic adsorptive force, for example, a structure comprising an electrode and a dielectric film surrounding the electrode. In order to increase yield rate of wafers, on the other hand, it is essentially required to maintain a constant temperature of the wafer reacting to plasma during a process, for example, during an etching process. When the temperature of the entire wafer is not uniformly maintained, defectiveness, such as poor distribution of critical dimensions on the wafer is generated during the etching process.

The electrostatic chuck is provided at the surface thereof with a refrigerant channel, for example, a helium (He) channel, for cooling the wafer to maintain a constant temperature of the wafer. The shape of such a helium channel directly affects the temperature distribution of the entire wafer. For this reason, various attempts have been made to change the shape of the helium channel to accomplish uniform temperature control on the wafer.

At present, a dielectric film, in which an electrode for supplying electric power necessary to generate an electrostatic force is disposed, is formed by coating a dielectric material. The dielectric film formed by coating the dielectric material has a relatively large thickness, and therefore, it is necessary that high direct current voltage be applied to the electrode in order to generate a sufficient electrostatic force. However, application of such high direct current voltage leads to damage to semiconductor devices formed on the wafer, which decreases yield rate of wafers.

Also, anodized film may be easily peeled off due to arcing at the edge part of the electrostatic chuck when high direct current voltage is applied. As a result, the service life of the electrostatic chuck may be reduced, and impurities may be generated in the reaction chamber.

It is first required to maintain a constant temperature of the chuck in order to accomplish uniform temperature control on the wafer. To this end, various attempts have been made. For example, a cooling channel may be provided at the chuck base to maintain a constant temperature of the chuck, by which the wafer can be uniformly cooled.

The plan shape and the arrangement of the cooling channel formed at the chuck base are considered parameters for uniformly cooling the chuck. Especially, improvement of the plan shape of the cooling channel to effectively reduce temperature deviation at the chuck or the wafer has been devised.

### DISCLOSURE OF THE INVENTION

Therefore, the present invention has been made in view of the above problems, and it is an object of the present invention to provide an electrostatic chuck having a cooling channel that is capable of minimizing temperature deviation of a wafer mounted on the electrostatic chuck, thereby improving uniformity of critical dimensions in the wafer, and therefore, increasing yield rate of wafers.

It is another object of the present invention to provide a chuck base having a newly shaped cooling channel that is capable of maintaining a constant chuck temperature, thereby effectively reducing temperature deviation generated at the chuck or a wafer and effectively cooling the wafer.

In accordance with one aspect of the present invention, the above and other objects can be accomplished by the provision of an electrostatic chuck comprising: a chuck base for supporting a wafer; a dielectric film mounted on the chuck base, the dielectric film having an electrode for supplying direct current voltage to provide an electrostatic force necessary to fix the wafer, the electrode being disposed in the dielectric film; and a cooling channel for supplying refrigerant to the dielectric film to control the temperature of the wafer, the cooling channel comprising: at least two first cooling channel parts formed at the surface of the dielectric film corresponding to the edge part of the wafer such that the first cooling channel parts form concentric circles; second cooling channel parts formed at the surface of the dielectric film such that the first cooling channel parts are connected to each other through the second cooling channel parts; first through channels formed through the dielectric film for supplying the refrigerant to the first and second cooling channel parts; and a second through channel formed through the center of the dielectric film for supplying the refrigerant to the center of the wafer.

Preferably, the dielectric film is a dielectric sheet comprising stacked dielectric sheet parts, between which the electrode is disposed, the dielectric sheet being attached to the chuck base while being compressed.

Preferably, the inside part of the first cooling channel parts, which is near to the center of the dielectric film, is disposed within the distance corresponding to not more than ¼ of the diameter of the wafer from the circumference of the dielectric film at the most.

Preferably, the number of the second cooling channel parts is eight, and the first through channels, whose number is equal to that of the second cooling channel parts, are connected to the second cooling channel parts adjacent to the connections between the second cooling channel parts and the outside part of the first cooling channel parts, respectively.

In accordance with another aspect of the present invention, there is provided a chuck base for supporting and cooling a chuck on which a wafer is located. The chuck base comprises: a base body for supporting a chuck, on which a wafer is located; and a cooling channel for cooling the chuck, the cooling channel comprising: a curved part, which extends outward from the center of the chuck base under the surface of the chuck base, which is opposite to the chuck, in the shape of a cross; and a circular part connected to the curved part, the circular part being formed in the shape of a circle around the cross-shaped part.

Preferably, the chuck base further comprises: a connection part disposed between one end of the cross-shaped part and one end of the circular part for connecting the cross-shaped part and the circular part, whereby the cooling channel begins at the other end of the cross-shaped part, and ends at the other end of the circular part.

Preferably, the base body is provided with four first through holes, through which lift pins for locating the wafer on the chuck are inserted, and the cooling channel is curved such that the four first through holes are disposed between the cross-shaped part and the circular part, and the cross-shaped part extends around the first through holes.

Preferably, the base body is provided with second through holes for supplying electric power necessary to generate an electrostatic force to the chuck, and the cooling channel is curved such that the cross-shaped part extends around the inside parts of the second through holes.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a view schematically showing the structure of an electrostatic chuck according to a preferred embodiment of the present invention;

FIG. 2 is a plan view schematically showing the front surface of a chuck base constituting the electrostatic chuck according to the preferred embodiment of the present invention;

FIG. 3 is a plan view schematically showing the rear surface of the chuck base constituting the electrostatic chuck according to the preferred embodiment of the present invention;

FIG. 4 is a sectional view schematically showing the chuck base constituting the electrostatic chuck according to the preferred embodiment of the present invention;

FIG. 5 is an enlarged plan view of the A part of FIG. 3 illustrating the chuck base constituting the electrostatic chuck according to the preferred embodiment of the present invention;

FIG. 6 is a sectional view schematically showing connection at the B part of FIG. 3;

FIG. 7 is a sectional view schematically showing a lift hole of FIG. 2;

FIGS. 8 and 9 are plan and sectional views schematically showing a sheet-shaped dielectric film constituting the electrostatic chuck according to the preferred embodiment of the present invention, respectively, the sheet-shaped dielectric film being attached to the chuck base while being compressed;

FIG. 10 is an enlarged plan view of the C part of FIG. 8 illustrating the sheet-shaped pressed dielectric film constituting the electrostatic chuck according to the preferred embodiment of the present invention;

FIG. 11 is a sectional view schematically showing connection at the C part of FIG. 8;

FIG. 12 is a plan view schematically showing a first modification of a cooling channel according to the preferred embodiment of the present invention;

FIG. 13 is a plan view schematically showing a second modification of a cooling channel according to the preferred embodiment of the present invention;

FIG. 14 is a plan view schematically showing the E part of FIG. 13;

FIG. 15 is a sectional view schematically showing a chuck base according to a preferred embodiment of the present invention;

FIG. 16 is a plan view schematically showing the plan shape of a cooling channel formed at the chuck base according to the preferred embodiment of the present invention; and

FIG. 17 is a sectional view taken along line A-A′ of FIG. 2 illustrating the plan shape of the cooling channel formed at the chuck base according to the preferred embodiment of the present invention.

### BEST MODE FOR CARRYING OUT THE INVENTION

An electrostatic chuck according to a preferred embodiment of the present invention is schematically shown in FIGS. 1 to 14.

FIG. 1 shows the structure of the electrostatic chuck according to the preferred embodiment of the present invention.

Referring to FIG. 1, the electrostatic chuck according to the preferred embodiment of the present invention comprises a chuck base 200 for supporting a wafer 100, on which an etching process is performed. Under the chuck base 200 may be disposed a chuck body (not shown) for supporting the chuck base 200.

On the chuck base 200 is formed a dielectric film 400. Generally, the dielectric film 400 may be formed by anodizing. In the preferred embodiment of the present invention, however, an additional dielectric sheet, which is manufactured in the shape of a sheet, is attached to the surface of the chuck base 200 while being compressed. In the illustrated embodiment, the dielectric sheet comprises a first dielectric sheet part 401 and a second dielectric sheet part 402 stacked on the first dielectric sheet part 401, although the dielectric sheet may comprise a plurality of stacked dielectric sheet parts.

Between the first dielectric sheet part 401 and the second dielectric sheet part 402 is disposed a thin electrode 300. As a result, the electrode 300 is provided in the dielectric film 400. The electrode 300 may be made of a conductive metal material, such as copper (Cu), aluminum (Al) or molybdenum (Mo). Alternatively, such a conductive metal material may be coated on the first dielectric sheet part 401.

In the case that the dielectric film 400 is formed by attaching and compressing the dielectric sheet, it is possible to form the dielectric sheet with a dielectric material having excellent dielectric characteristics, and therefore, more excellent dielectric characteristics are realized. Also in the case that the dielectric film 400 is formed by attaching and compressing the dielectric sheet, it is possible to uniformly decrease the thickness of the entire dielectric film 400, especially, the thickness of the second dielectric sheet part 402 between the electrode 300 and the wafer 100. Consequently, an electrostatic adsorptive force can be sufficiently generated although low direct current voltage (V) is applied to the electrode 300.

If the thickness of the dielectric film 400 is approximately 1.3 mm, the thickness of the first dielectric sheet part 401 is approximately 0.7 mm, which is relatively large, and the thickness of the second dielectric sheet part 402 is approximately 0.3 mm, which is relatively small. As a result, the thickness of the electrode 300 is approximately 0.3 mm.

Application of low direct current voltage (V) reduces the probability of occurrence of arcing and prevents the dielectric film 400 from being damaged due to such arcing or the anodized film from being peeled off, and therefore, the service life of the electrostatic chuck from being decreased. In addition, impurities are effectively prevented from being generated in a reaction chamber.

Also, application of low direct current voltage (V) reduces the electric charge in the second dielectric sheet part 402, and therefore, it is possible to more smoothly separate the wafer 100 from the chuck base 200. Specifically, the net charge when the wafer 100 is separated rapidly amounts to zero, and therefore, the wafer 100 can be separated without sliding or being damaged.

Application of low direct current voltage (V) is very advantageous in preventing spark discharge, which may be generated under lower pressure, for example, several mTorr, in the reaction chamber when the wafer 100 is separated.

At the surface of the dielectric film 400 of the electrostatic chuck is formed a cooling channel 500 for cooling the wafer 100. The cooling channel 500 supplies helium (He) as refrigerant to the rear surface 100 for cooling the wafer 100 to control the temperature of the wafer 100, which will be described below in detail. The conventional type of cooling channel causes the difference in temperature between the center part and the edge part of the wafer, and therefore, it is difficult to control critical dimensions of the device. The present invention proposes a new type of cooling channel 500 that is capable of accomplishing uniform temperature distribution throughout the wafer 100, and therefore, minimizing temperature deviation.

Although not shown in FIG. 1, a path for supplying helium as refrigerant to the cooling channel 500 formed at the surface of the dielectric film 400 comprises a through hole (not shown) extending from the chuck base 200 to the cooling channel 500. However, controlling the temperature of the wafer 100 is substantially dependent upon the shape of the cooling channel 500 formed at the surface of the dielectric film 400, and therefore, the cooling channel 500 will be described below in detail with reference to the accompanying drawings.

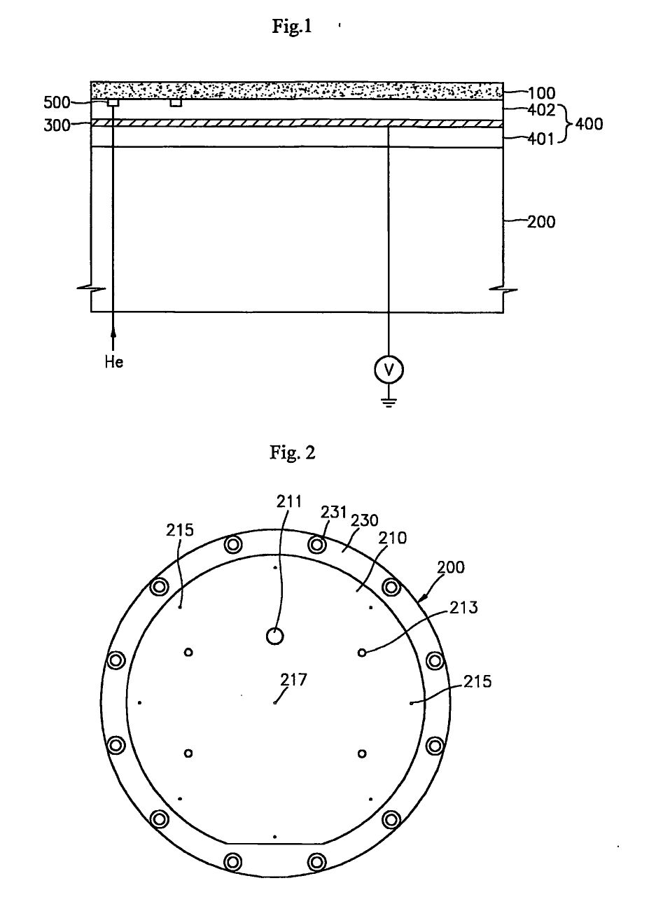

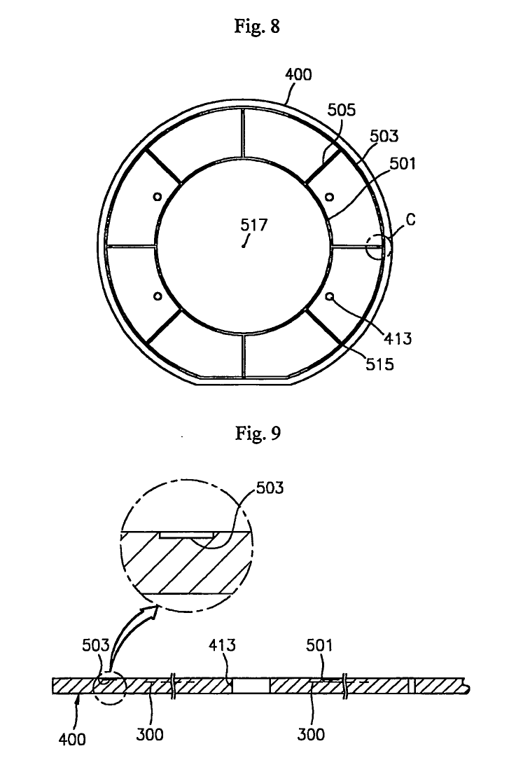

FIGS. 2 to 6 show the chuck base constituting the electrostatic chuck according to the preferred embodiment of the present invention, and FIGS. 8 to 11 show the sheet-shaped dielectric film constituting the electrostatic chuck according to the preferred embodiment of the present invention, the sheet-shaped dielectric film being attached to the chuck base while being compressed.

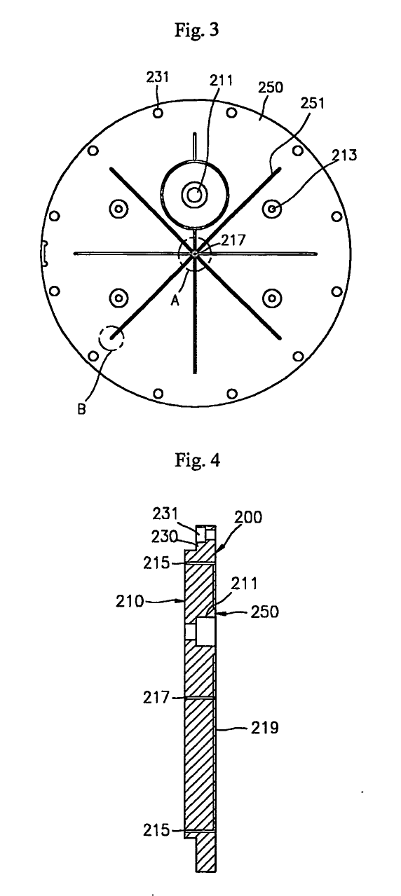

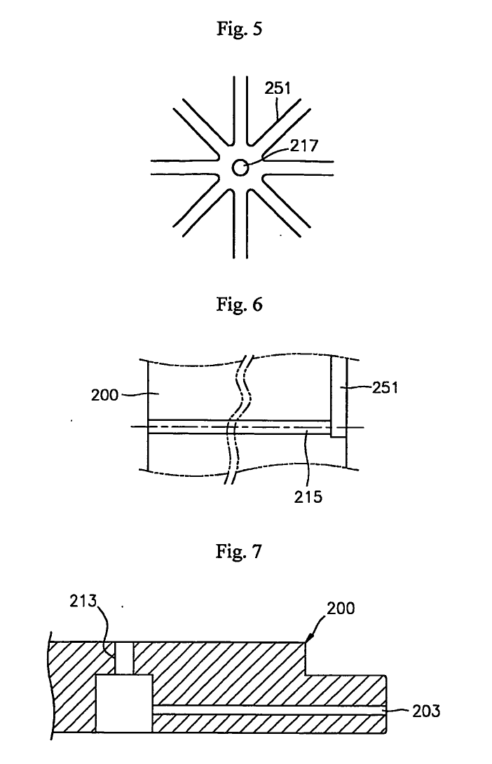

Specifically, FIG. 2 is a plan view schematically showing the front surface of the chuck base constituting the electrostatic chuck according to the preferred embodiment of the present invention. FIG. 3 is a plan view schematically showing the rear surface of the chuck base constituting the electrostatic chuck according to the preferred embodiment of the present invention. FIG. 4 is a sectional view schematically showing the chuck base constituting the electrostatic chuck according to the preferred embodiment of the present invention. FIG. 5 is an enlarged plan view of the A part of FIG. 3. FIG. 6 is a sectional view schematically showing connection at the B part of FIG. 3. FIG. 7 is a sectional view schematically showing a lift hole of FIG. 2.

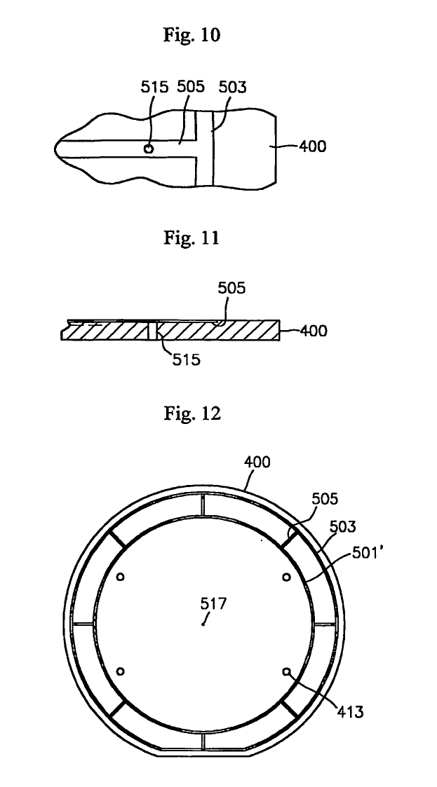

FIGS. 8 and 9 are plan and sectional views schematically showing a sheet-shaped dielectric film constituting the electrostatic chuck according to the preferred embodiment of the present invention, respectively, the sheet-shaped dielectric film being attached to the chuck base while being compressed. FIG. 10 is an enlarged plan view of the C part of FIG. 8, and FIG. 11 is a sectional view schematically showing connection at the C part of FIG. 8.

Referring first to FIGS. 2 to 7, the chuck base 200 is made of aluminum, and is constructed such that a step is formed between the front surface 210 of the chuck base 200, which faces the wafer 100, and an edge part 230 of the chuck base 200, as shown in FIG. 2 and FIG. 4. The front surface 210 of the chuck base 200 has its edge shaped according to the shape of the wafer 100. At this time, the front surface 210 of the chuck base 200 is formed such that the width of the front surface 210 is slightly narrower than that of the water 100. For example, the diameter of the front surface 210 of the chuck base 200 is approximately 196.1 mm if the diameter of the wafer 100 is 200 mm.

The edge part 230 is provided with a plurality of through holes 231, through which fixing members of the chuck base 200, for example, bolts, are inserted. The entire edge part 230 is anodized such that an insulation film covers the edge part. However, the front surface 210 of the chuck base 200 is maintained bare. To the front surface 210 is attached the dielectric film 400 while being compressed as shown in FIGS. 8 to 11.

As shown in FIGS. 2, 3 and 4, the chuck base 200 has a plurality of through holes. Specifically, the chuck base 200 has an electric source connection through hole 211, through which a lead-in wire (not shown) for supplying direct current voltage to the electrode 300 disposed in the dielectric film 400 is inserted. Also, the chuck base 200 has lift holes 213, through which lift pins (not shown) for separating the wafer 100 are inserted. In the illustrated embodiment, the number of the lift holes 213 is four such that a 4-pin lifter can be used.

Referring to FIG. 7, an air hole 203 is connected to the lift holes 213. The air hole 203 is a through hole connected to the lift holes 213 through the chuck base 200. The air hole 203 serves to solve the problem of the lift pins not being smoothly operated due to repletion of air when the wafer 100 moves up and down. In other words, air smoothly flows through the air hole 203, and therefore, the lift pins are smoothly operated. As a result, the wafer smoothly moves up and down.

Referring back to FIGS. 2, 3 and 4, the chuck base 200 has a plurality, for example, eight, of first supply through holes 215 for supplying helium as refrigerant to the cooling channel 500 formed at the surface of the dielectric film 400. The first supply through holes 215 are aligned with first through channels formed at the dielectric film 400, which will be described below in detail. The first supply through holes 215 are formed at different positions of the chuck base 200 corresponding to the edge of the wafer 100 such that the first supply through holes 215 together form a concentric circle. Also, a second supply through hole 217 is formed at a position of the chuck base 200 corresponding to the center of the wafer 100. The second supply through hole 217 is aligned with a second through channel formed at the dielectric film 400, which will be described below in detail.

Referring to FIGS. 3 and 4, the chuck base 200 is provided at the rear surface 250 thereof with groove-shaped distribution channels 251 for simultaneously distributing helium as refrigerant to the first supply through holes 215 and the second supply through hole 217. The distribution channels 251 are radial grooves intersecting one another at the middles thereof as shown in FIG. 3.

The second supply through hole 217 is connected to the intersecting part of the distribution channels 251, as shown in FIG. 5, which is an enlarged plan view of the A part of FIG. 3. Also, the first supply through holes 215 are connected to the ends of the distribution channels 251, respectively.

Consequently, helium is simultaneously distributed to the first supply through holes 215 and the second supply through hole 217 through the distribution channels 251.

Referring to FIGS. 8 to 11, the dielectric film 400 is formed in the shape of stacked sheets such that the electrode 300 is disposed in the dielectric film 400. As shown in FIG. 8, the shape of the dielectric film 400 corresponds to the shape of the chuck base 200. The dielectric film 400 is provided with lift holes 413, which are aligned with the lift holes 213 formed at the chuck base 200, respectively, such that the lift pins can be inserted into the lift holes 413 of the dielectric film 400. In the illustrated embodiment, the number of the lift holes 413 is four such that a 4-pin lifter can be used.

The cooling channel 500 is formed at the upper surface of the dielectric film 400 for controlling the temperature of the wafer 100, i.e., cooling the wafer 100. The cooling channel 500 comprises at least two groove-shaped first cooling channel parts 501 and 503, which are disposed on the dielectric film 400 corresponding to the edge part of the wafer 100 such that the first cooling channel parts 501 and 503 form concentric circles. Between the first cooling channel parts 501 and 503 are disposed a plurality of second cooling channel parts 505, which are arranged in the radial direction such that the first cooling channel parts 501 and 503 are connected to each other through the second cooling channel parts 505. The thickness of the entire dielectric film 400 is merely approximately 1.3 mm, and therefore, each of the first cooling channel parts 501 and 503 and/or the second cooling channel parts 505 is formed in the shape of a groove having a depth of approximately 0.1 mm and a width of approximately 1 mm.

The dielectric film 400 is provided with first through channels 515, which are formed though the dielectric film 400 for supplying helium as refrigerant to the first cooling channel parts 501 and 503 and the second cooling channel parts 505. The first through channels 515 are aligned with the first supply through holes 215 formed at the chuck base 200, respectively. At a position of the dielectric film 400 corresponding to the center of the wafer 100 is formed a second through channel 517 for injecting helium as refrigerant to the rear surface of the wafer 100. Each of the first and second through channels 515 and 517 has a diameter of approximately 0.5 mm.

In the cooling channel 500 with the above-stated construction, the first and second cooling channel parts 501 and 505 are disposed adjacent to the edge part of the wafer 100. In other words, the cooling channel 500 is constructed such that a relatively large portion of refrigerant is supplied to the edge part of the wafer 100 as compared to the center part of the wafer 100. Especially, the cooling channel 500 is constructed such that only helium as refrigerant injected from the second through channel 517 is supplied to the center part of the wafer 100. Consequently, the concentrically arranged first cooling channel parts 501 and 503 or the second cooling channel parts 505, which are connection channels, do not extend to the center part of the wafer 100.

For example, the cooling channel 500 is constructed such that the inside part of the first cooling channel parts 501 and 503, i.e., the first cooling channel part 501, is disposed within the distance corresponding to not more than ¼ of the diameter of the wafer 100 from the circumference of the wafer 100 at the most. If the diameter of the wafer 100 is 200 mm, the first inner cooling channel part 501 is approximately 38 mm from the circumference of the wafer 100 or the circumference of the dielectric film 400. Practically, the position of the first cooling channel part 501 may be disposed adjacent to the lift holes 413 or the circumference of the dielectric film 400 or the wafer 100.

If the cooling channel 500 is disposed adjacent to the edge part of the wafer 100, the temperate at the edge part of the wafer 100 can be effectively controlled. When a dry etching process is performed, the temperature deviation is greater at the edge part of the wafer 100 than at the center part of the wafer 100. According to the present invention, however, the cooling channels 501, 503 and 505, through which helium flows, are concentrically disposed at the positions of the dielectric film 400 corresponding to the edge part of the wafer 100, whereby such temperature deviation is effectively prevented.

Helium can be simultaneously injected through the second through channel 517 and the first through channels 515, which is accomplished by the provisions of the distribution channels 251 formed at the rear surface 250 of the chuck base 200 as described above with reference to FIG. 3.

The shape of the cooling channel 500 according to the preferred embodiment of the present invention may be variously modified. Nevertheless, concentrically arranged cooling channels and connection channels are disposed adjacent to the edge part of the wafer in all modifications.

FIG. 12 is a plan view schematically showing a first modification of the cooling channel according to the preferred embodiment of the present invention.

Referring to FIG. 12, the modified cooling channel is different from the cooling channel according to the preferred embodiment of the present invention as shown in FIG. 8 in that the arrangement of first cooling channels corresponding to the first cooling channels 501 and 503 are changed. As shown in FIG. 12, a first inner cooling channel 501′ of the modified cooling channel is disposed outside the lift holes 413. In other words, the first inner cooling channel 501′ is disposed adjacent to the circumference of the dielectric film 400 or the circumference of the wafer 100. For example, the first cooling channel 501′ is approximately 22 mm from the circumference of the dielectric film 400.

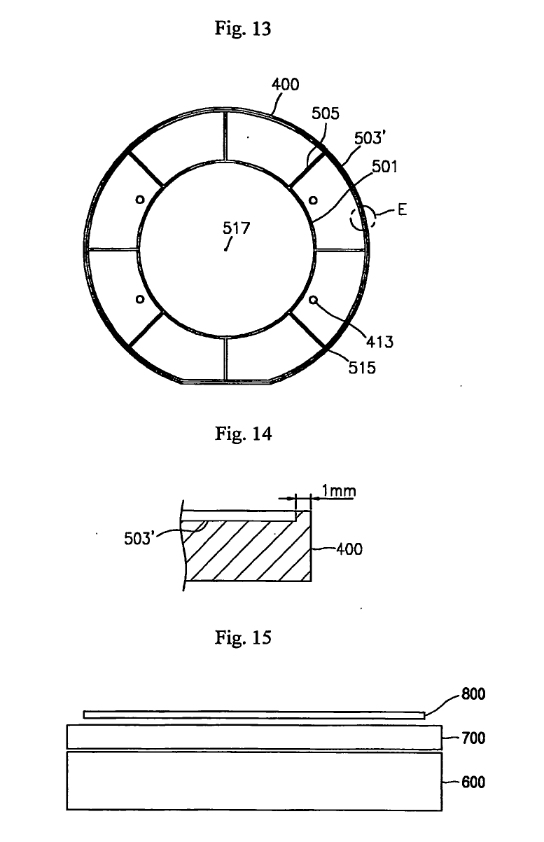

FIG. 13 is a plan view schematically showing a second modification of the cooling channel according to the preferred embodiment of the present invention. FIG. 14 is a plan view schematically showing the E part of FIG. 13.

Referring to FIGS. 13 and 14, the modified cooling channel is different from the cooling channel according to the preferred embodiment of the present invention as shown in FIG. 8 in that an outside first cooling channel corresponding to the outside first cooling channel 503 of the first cooling channels 501 and 503 is disposed maximally adjacent to the circumference of the dielectric film 400. Specifically, an outside first cooling channel 503′ of the modified cooling channel is approximately 1 mm or less from the circumference of the dielectric film 400, as shown in FIG. 5. The position where the outside first cooling channel 503′ is disposed is the part where devices are not substantially formed on the wafer 100, i.e., the part corresponding to a width of approximately 3 mm from the circumference of the wafer. The outside first cooling channel 503′ is disposed at the above-mentioned part, i.e., the edge exclusion part, whereby temperature control is more effectively accomplished.

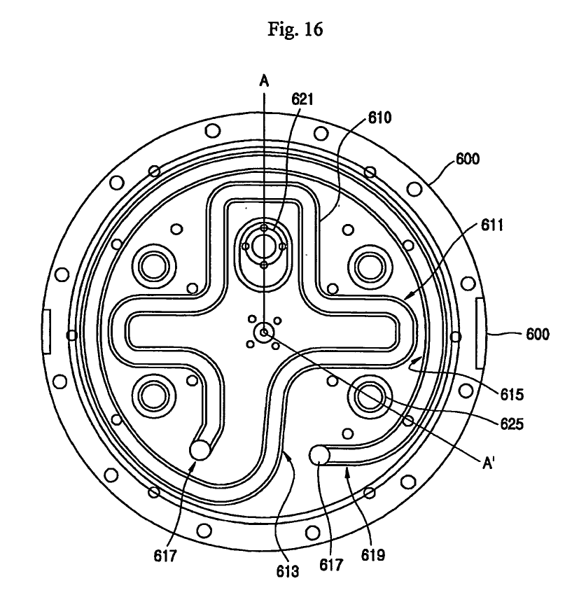

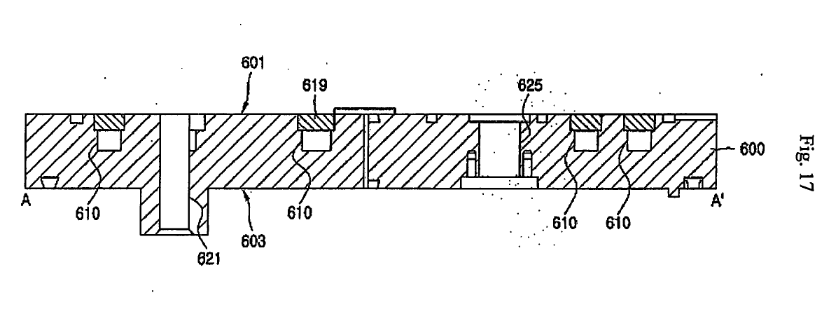

FIG. 15 is a sectional view schematically showing a chuck base according to a preferred embodiment of the present invention. FIG. 16 is a plan view schematically showing the plan shape of a cooling channel formed at the chuck base according to the preferred embodiment of the present invention. FIG. 17 is a sectional view taken along line A-A′ of FIG. 2 illustrating the plan shape of the cooling channel formed at the chuck base according to the preferred embodiment of the present invention.

Referring to FIG. 15, a chuck base 600 according to the preferred embodiment of the present invention is disposed at the rear surface of a chuck 700, which is mounted in a process chamber of chamber equipment used in a semiconductor device manufacturing process, for example, plasma dry etching equipment. The chuck 700 may be an electrostatic chuck. Specifically, the chuck 700, which comprises a thin film made of aluminum oxide (Al₂O₃) and an electrode disposed under the thin film for generating an electrostatic force, is disposed on the chuck base 600. Alternatively, the chuck 700 may be fixedly mounted on the chuck base 600 through bolt-nut engagement.

The temperature of a semiconductor wafer 800, which is located on the chuck 700, may be increased in the course of the process, and therefore, the temperature of the chuck 700 may be increased. Such increase of temperature greatly affects the process, and as a result, undesired defectiveness, such as nonuniform critical dimensions, may be caused. For this reason, a cooling unit for controlling or compensating for the increase of temperature to maintain a constant temperature of the wafer 800 or the chuck 700 is required.

The preferred embodiment of the present invention provides a cooling channel, serving as the cooling unit, formed at the chuck base 600.

Referring to FIGS. 7 and 8, the chuck base 600 according to the preferred embodiment of the present invention comprises a base body for supporting the chuck 700 (see FIG. 15). In the base body under the upper surface 601 of the base body of the chuck base 600 opposite to the rear surface of the chuck 700 is provided a cooling channel 610. The reason why the cooling channel 610 is provided adjacent not to the lower surface 603 of the chuck base 600 but to the upper surface 601 of the chuck base 600 is to more effectively transfer heat to the chuck 700. As a result, the chuck 700 is more effectively cooled, and therefore, the semiconductor wafer located on the chuck 700 is more effectively cooled.

The cooling channel 610 may be formed by forming a groove at the upper surface 601 of the base body of the chuck base 600 and placing a cover part 619 on the groove such that the groove is covered by the cover part 619. The cover part 619 is placed on the groove, and is then fixed to the upper surface of the base body of the chuck base 600 by welding. As a result, the groove is hermetically sealed, and therefore, refrigerant, for example, demineralized water, is prevented from flowing out of the cooling channel 610 or onto the chuck base 600.

The cooling channel 610 is disposed over a broad area of the chuck base such that the entire area of the chuck 700 and the entire area of the semiconductor wafer 800 can be effectively and uniformly cooled by the cooling channel 610. Specifically, the cooling channel 610 is formed under the upper surface 601 of the chuck base 600 in the shape of a curve such that the cooling channel 610 extends over the broad area of the chuck base.

For example, the cooling channel 610 comprises a curved part, which extends outward from the center of the upper surface 601 of the chuck base 600 in the shape of a cross, i.e., a cross-shaped part 611, as shown in FIG. 16. The cross-shaped part 611 is a part of the cooling channel 610 that is curved in the shape of a cross. Also, the cooling channel 610 comprises a circular part 615, which is formed in the shape of a circle around the cross-shaped part 611. The circular part 615 is connected to the cross-shaped part 611 such that circular part 615 communicates with the cross-shaped part 611.

Inlet and outlet ports 617 for allowing refrigerant to be introduced into the cooling channel 610 therethrough are formed such that the inlet and outlet ports 617 are opposite to each other. Specifically, one of the inlet and outlet ports 617 is disposed at one end of the cross-shaped part 611, and therefore, the cooling channel 610 begins at the inlet and outlet port 617 disposed at the end of the cross-shaped part 611. Also, the other inlet and outlet port 617 is disposed at one end of the circular part 615, and therefore, the cooling channel 610 ends at the inlet and outlet port 617 disposed at the end of the circular part 615. Consequently, the cooling channel 610 extends from the inlet and outlet port 617 disposed at the end of the cross-shaped part 611 to the inlet and outlet port 617 disposed at the end of the circular part 615. The cooling channel may further comprise a connection part 613 disposed between the other end of the cross-shaped part 611 and the other end of the circular part 615 for connecting the cross-shaped part 611 and the circular part 615. At this time, it is preferable that the two inlet and outlet ports 617 are opposite to each other while the connection part 613 is disposed between the two inlet and outlet ports 617.

The circular part 615 of the cooling channel 610 is disposed along the circumference the chuck base in the shape of a circle while the cross-shaped part 611 of the cooling channel 610 is disposed inside the circular part 615. The chuck base 600 is generally provided with a plurality of through holes 621 and 625. For example, lift pins (not shown), which are used to locate the semiconductor wafer 800 on the chuck 700 or remove the semiconductor wafer 800 from the chuck 700, support the semiconductor wafer 800 through the chuck base 600 and the chuck 700. Consequently, the first through holes 621 is formed at the chuck base 600 such that the lift pins can be inserted through the first through holes 621, respectively.

The number of the first through holes 621 corresponds to the number of the lift pins. In the illustrated embodiment of the present invention, the number of the lift pins is four such that the semiconductor wafer 800 can be stably located on the chuck base, and therefore, four first through holes 121 are disposed as shown in FIG. 2.

It is required that the cooling channel 110 not extend over the first through holes 121 and the cooling channel 110 extend over a broad area of the chuck base. Consequently, the first through holes 121 are disposed between the cross-shaped part 111 and the circular part 115 of the cooling channel 110, and therefore, the cross-shaped part 111 of the cooling channel 110 is curved such that the cross-shaped part 111 extends around the first through holes 121.

When the chuck 700 is an electrostatic chuck as shown in FIG. 15, the base body of the chuck base 600 is provided with second through holes 625 for supplying electric power to the electrode, which generates an electrostatic force. Since the second through holes 625 are provided to supply electric power to the electrode, it is required that the cooling channel 610 not extend over the second through holes 625. Consequently, the cooling channel 610 is curved such that the cooling channel 610 extends around the second through holes 625. Specifically, the cooling channel 610 is curved in the shape of a cross such that the second through holes 625 are disposed inside the cross-shaped part 611 of the cooling channel 610, as shown in FIG. 16.

In addition to the cooling channel 610, various structures, such as nut-shaped grooves, for connection between the chuck base 600 and the chuck 700, for example, bolt-nut connection, may be provided at the upper surface 601 of the chuck base 600. Also, various structures, such as nut-shaped grooves, for connection between the chuck base 600 and the chamber may be provided at the lower surface 603 of the chuck base 600. Furthermore, the chuck base 600 may be provided at the center part of the upper surface 601 thereof with a helium supply hole for supplying helium (He) to the rear surface of the wafer 800.

As apparent from the above description, the cooling channel, through which helium as refrigerant flows, are disposed at the electrostatic chuck corresponding to the edge part of the wafer according to the present invention. Consequently, the present invention has the effect of more effectively controlling the temperature of the edge part of the wafer. When a dry etching process is performed, the temperature deviation is greater at the edge part of the wafer than at the center part of the wafer. According to the present invention, however, such temperature deviation is compensated for, and therefore, occurrence of the temperature deviation is effectively prevented.

In the preferred embodiment of the present invention, the dielectric film is formed by attaching and compressing the dielectric sheet. As a result, it is possible to form the dielectric sheet with a dielectric material having excellent dielectric characteristics, and therefore, more excellent dielectric characteristics are realized. Also, it is possible to uniformly decrease the thickness of the second dielectric sheet part between the electrode and the wafer. Therefore, an electrostatic adsorptive force can be sufficiently generated although low direct current voltage (V) is applied to the electrode. Consequently, the present invention has the effect of preventing the electrostatic chuck or the wafer from being damaged due to arcing, remarkably increasing the service life of the electrostatic chuck, and considerably increasing yield rate of wafers.

In the chuck base according to the present invention, the cooling channel is disposed under the upper surface of the chuck base while the cooling channel is curved such that the cooling channel extends over the broad area of the chuck base. As a result, the entire area of the chuck disposed on the chuck base is more effectively and uniformly cooled, and therefore, the entire area of the wafer located on the chuck is more effectively and uniformly cooled. Consequently, the present invention has the effect of effectively preventing occurrence of temperature deviation at the wafer or the chuck, and maintaining a constant temperature of the wafer or the chuck. Especially, the cooling channel comprises the cross-shaped part and the circular part disposed around the cross-shaped part, and therefore, more uniform temperature control is accomplished over the entire area of the chuck or the wafer.

### INDUSTRIAL APPLICABILITY

The present invention is applied to the industrial field using a reaction chamber having an electrostatic chuck for supporting wafers and a chuck base disposed under the electrostatic chuck.

1. An electrostatic chuck comprising:
a chuck base for supporting a wafer,
a dielectric film mounted on the chuck base, the dielectric film having an electrode for supplying direct current voltage to provide an electrostatic force necessary to fix the wafer, the electrode being disposed in the dielectric film; and
a cooling channel for supplying refrigerant to the dielectric film to control the temperature of the wafer, the cooling channel comprising:
at least two first cooling channel parts formed at the surface of the dielectric film corresponding to the edge part of the wafer such that the first cooling channel parts form concentric circles;
second cooling channel parts formed at the surface of the dielectric film such that the first cooling channel parts are connected to each other through the second cooling channel parts;
first through channels formed through the dielectric film for supplying the refrigerant to the first and second cooling channel parts; and
a second through channel formed through the center of the dielectric film for supplying the refrigerant to the center of the wafer.

2. The chuck as set forth in claim 1, wherein the dielectric film is a dielectric sheet comprising stacked dielectric sheet parts, between which the electrode is disposed, the dielectric sheet being attached to the chuck base while being compressed.

3. The chuck as set forth in claim 1, wherein the inside part of the first cooling channel parts, which is near to the center of the dielectric film, is disposed within the distance corresponding to not more than ¼ of the diameter of the wafer from the circumference of the dielectric film at the most.

4. The chuck as set forth in claim 1, wherein
the number of the second cooling channel parts is eight, and
the first through channels, whose number is equal to that of the second cooling channel parts, are connected to the second cooling channel parts adjacent to the connections between the second cooling channel parts and the outside part of the first cooling channel parts, respectively.

5. A chuck base comprising:
a base body for supporting a chuck, on which a wafer is located; and
a cooling channel for cooling the chuck, the cooling channel comprising:
a curved part, which extends outward from the center of the chuck base under the surface of the chuck base, which is opposite to the chuck, in the shape of a cross; and
a circular part connected to the curved part, the circular part being formed in the shape of a circle around the cross-shaped part.

6. The base as set forth in claim 5, further comprising:
a connection part disposed between one end of the cross-shaped part and one end of the circular part for connecting the cross-shaped part and the circular part, whereby
the cooling channel begins at the other end of the cross-shaped part, and ends at the other end of the circular part.

7. The base as set forth in claim 5, wherein
the base body is provided with four first through holes, through which lift pins for locating the wafer on the chuck are inserted, and
the cooling channel is curved such that the four first through holes are disposed between the cross-shaped part and the circular part, and the cross-shaped part extends around the first through holes.

8. The base as set forth in claim 5, wherein
the base body is provided with second through holes for supplying electric power necessary to generate an electrostatic force to the chuck, and
the cooling channel is curved such that the cross-shaped part extends around the inside parts of the second through holes.
